(19) United States
(12) Patent Application Publication
(10) Pub. No.: US 2026/0362953 A1
(43) Pub. Date: Nov. 12, 2026

(54) DISPLAY MODULE, METHOD FOR MANUFACTURING THE SAME, AND ELECTRONIC DEVICE INCLUDING THE DISPLAY MODULE

(71) Applicant: Samsung Display Co., Ltd., Yongin-si (KR)

(72) Inventor: HO LIM, Yongin-si (KR)

(21) Appl. No.: 19/575,657

(22) Filed: Mar. 23, 2026

(30) Foreign Application Priority Data
May 12, 2025 (KR) 10-2025-0060862

(51) Int. Cl. H10K 59/80; H10K 59/12

(52) U.S. Cl. CPC H10K 59/8792; H10K 59/1201

(57) ABSTRACT

A display module includes a base substrate, a display layer on the base substrate and including a light-emitting element, and a black printing layer spaced apart from the display layer with the base substrate therebetween and on a lower surface of the base substrate, wherein the black printing layer includes a base portion including a polymerized oligomer and monomer, a black colorant, a conductor, and a moisture absorbent.

### CROSS-REFERENCE TO RELATED APPLICATION

The present application claims priority to and the benefit of Korean Patent Application No. 10-2025-0060862, filed on May 12, 2025, in the Korean Intellectual Property Office, the entire content of which is incorporated herein by reference.

### BACKGROUND

Embodiments of the present disclosure relate to a display module, a method for manufacturing the display module, and an electronic device including the display module. For example, embodiments of the present disclosure relate to a display module including a black printing layer, a method for manufacturing the display module, and an electronic device including the display module.

Multimedia electronic devices, such as televisions, mobile phones, tablet computers, navigation devices, game consoles, and/or wearable devices, may include a display module for displaying images. Such display modules may improve image quality by attaching a black printing layer to the opposite side of a light-emitting surface, which may reduce external light reflection and prevent internal light sources from leaking out unnecessarily. The black printing layer may reduce interference that may occur inside electronic devices, ensuring accurate color expression and clarity.

Recently, research has been conducted into black printing layers that exhibit superior performance in physical properties, such as durability, and/or light blocking.

The above information disclosed in this Background section is intended to enhance understanding of the background of the disclosure and may contain information that does not constitute prior art.

### SUMMARY

Aspects of one or more embodiments of the present disclosure are directed to a display module exhibiting improved physical properties such as light blocking and surface resistance, and an electronic device including the same.

Aspects of one or more embodiments of the present disclosure are directed to a method for manufacturing a display module exhibiting improved physical properties such as light blocking and surface resistance.

Additional aspects will be set forth in part in the description which follows and, in part, will be apparent from the description, or may be learned by practice of the presented embodiments of the disclosure.

One or more embodiments of the present disclosure provide a display module including a base substrate, a display layer arranged on the base substrate and including a light-emitting element, and a black printing layer spaced and/or apart (e.g., spaced apart or separated) from the display layer with the base substrate therebetween and arranged on a lower surface of the base substrate, wherein the black printing layer includes a base portion in which an oligomer and a monomer are polymerized (e.g., including a polymerized oligomer and monomer), a black colorant, a conductor, and a moisture absorbent.

In one or more embodiments, the moisture absorbent may include at least one of inorganic particles or a highly moisture absorbent polymer.

In one or more embodiments, the inorganic particles may be at least one of zeolite, porous silica, metal-organic framework, alumina particles, nano clay, porous carbon, CaCl₂, NaCl, or bentonite clay, and the highly moisture absorbent polymer may be at least one of hemicellulose resin, pectin, silica gel, or starch particles.

In one or more embodiments, a display region corresponding to the display layer and a non-display region arranged on at least one side of the display region may be defined on the base substrate, and the black printing layer may be arranged to entirely overlap the display region.

In one or more embodiments, the base substrate may have a thickness of about 0.1 mm or greater and less than about 0.3 mm (e.g., of about 0.1 mm to 1.3 mm).

In one or more embodiments, the black printing layer may be formed by applying a black paste containing an oligomer, a monomer, a black colorant, a conductor, and a moisture absorbent to a thickness of about 8 μm or greater and less than about 14 μm.

In one or more embodiments, the black printing layer may have a surface resistance of about 10⁶ ohm/sq (Ω/sq) or greater and less than about 10¹⁰ ohm/sq (e.g., about 10⁶ ohm/sq to about 10¹⁰ ohm/sq).

In one or more embodiments, the black printing layer may have a pencil hardness of about 1H or greater and less than about 6H (e.g., about 1H to about 6H).

In one or more embodiments of the present disclosure, a method for manufacturing a display module includes forming a display layer including a light-emitting element on a base substrate, and forming a black printing layer spaced and/or apart (e.g., spaced apart or separated) from the display layer with the base substrate therebetween, on a lower surface of the base substrate, wherein the black printing layer may be formed from a black paste containing an oligomer, a monomer, a black colorant, a conductor, and a moisture absorbent.

In one or more embodiments, the forming of the black printing layer may include screen printing or inkjet printing the black paste to form a preliminary black printing layer, and curing the preliminary black printing layer.

In one or more embodiments, the moisture absorbent may be provided in an amount of about 1 wt % or greater and less than about 10 wt % (e.g., about 1 wt % to about 10 wt %) based on a total weight of the black paste.

In one or more embodiments, the oligomer may be provided in an amount of about 40 wt % or greater and less than about 60 wt % (e.g., about 40 wt % to about 60 wt %) based on a total weight of the black paste.

In one or more embodiments, the black paste may further include an initiator and a surfactant, and with respect to a total weight of the black paste, the oligomer may be provided in an amount of about 40 wt % or greater and less than about 60 wt % (e.g., about 40 wt % to about 60 wt %), the black colorant may be provided in an amount of about 1 wt % or greater and less than about 10 wt % (e.g., about 1 wt % to about 10 wt %), the conductor may be provided in an amount of about 1 wt % or greater and less than about 5 wt % (e.g., about 1 wt % to about 5 wt %), the moisture absorbent may be provided in an amount of about 1 wt % or greater and less than about 10 wt % (e.g., about 1 wt % to about 10 wt %), the initiator may be provided in an amount of about 5 wt % or greater and less than about 15 wt % (e.g., about 5 wt % to about 15 wt %), and the surfactant may be provided in an amount of about 1 wt % or greater and less than about 10 wt % (e.g., about 1 wt % to about 10 wt %).

In one or more embodiments, the black paste may have a viscosity reduced by less than about 10% (e.g., at most about 10%) from an initial viscosity after about 18 minutes at about 30 °C and about 85% relative humidity.

In one or more embodiments, the moisture absorbent may include at least one of inorganic particles or a highly moisture absorbent polymer, the inorganic particles may be at least one of zeolite, porous silica, metal-organic framework, alumina particles, nano clay, porous carbon, CaCl₂), NaCl, or bentonite clay, and the highly moisture absorbent polymer may be at least one of hemicellulose resin, pectin, silica gel, or starch particles.

In one or more embodiments of the present disclosure, an electronic device includes a display module configured to generate images, wherein the display module includes a base substrate, a display layer arranged on the base substrate and including a light-emitting element, and a black printing layer spaced and/or apart (e.g., spaced apart or separated) from the display layer with the base substrate therebetween and arranged on a lower surface of the base substrate, and wherein the black printing layer includes a base portion in which an oligomer and a monomer are polymerized (e.g., including a polymerized oligomer and monomer), a black colorant, a conductor, and a moisture absorbent.

In one or more embodiments, the moisture absorbent may include at least one of inorganic particles or a highly moisture absorbent polymer, the inorganic particles may be at least one of zeolite, porous silica, metal-organic framework, alumina particles, nano clay, porous carbon, CaCl₂, NaCl, or bentonite clay, and the highly moisture absorbent polymer may be at least one of hemicellulose resin, pectin, silica gel, or starch particles.

In one or more embodiments, the black printing layer may have a surface resistance of about 10⁶ ohm/sq (Ω/a) or greater and less than about 10¹⁰ ohm/sq (e.g., about 10⁶ ohm/sq to about 10¹⁰ ohm/sq), and a pencil hardness of about 1H or greater and less than about 6H (e.g., about 1H to about 6H).

In one or more embodiments, the electronic device may further include at least one of a processor, a memory, or a power module.

In one or more embodiments, the electronic device may include the display module, and may be a television, a monitor, an outdoor billboard, a personal computer, a laptop computer, a personal digital terminal, an in-vehicle device, a game console, a smartphone, a tablet, a smartwatch, or a camera.

For example, one or more embodiments provide a display module and an electronic device that achieve improved optical performance and mechanical reliability by incorporating a black printing layer on a lower surface of a base substrate, spaced (and/or apart) from the display layer. The black printing layer, formed from a black paste including a polymerized oligomer and monomer, a black colorant, a conductor, and a moisture absorbent, contributes to enhanced light blocking, reduced light leakage, and stable electrical properties. By maintaining high viscosity during processing, the black paste enables uniform layer thickness and mitigates coating defects, resulting in a black printing layer exhibiting a surface resistance of about 10⁶ to equal to or less than about 10¹⁰ ohms per square (Ω/sq) and a pencil hardness of about 1H to less than about 6H. These features, together with the defined composition ranges and manufacturing methods disclosed herein, allow the display module to provide enhanced display quality, durability, and environmental stability, and support integration into various electronic devices such as televisions, monitors, smartphones, tablets, and/or wearable devices.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1A is a block diagram of an electronic device according to one or more embodiments of the present disclosure;

FIG. 1B shows schematic views of electronic devices according to embodiments of the present disclosure;

FIG. 2 is a perspective view of an electronic device according to one or more embodiments of the present disclosure;

FIG. 3 is a perspective view of a display module according to one or more embodiments of the present disclosure;

FIG. 4 is a cross-sectional view of a display module taken along line I-I′ of FIG. 3, according to one or more embodiments of the present disclosure;

FIG. 5 is a cross-sectional view showing a portion of a display module taken along line II-II′ of FIG. 3, according to one or more embodiments of the present disclosure;

FIG. 6 is a schematic view showing a configuration of a black printing layer according to one or more embodiments of the present disclosure;

FIG. 7 is a flowchart showing a method for manufacturing a display module according to one or more embodiments of the present disclosure;

FIG. 8 is a flowchart showing a portion of a method for manufacturing a display module according to one or more embodiments of the present disclosure; and

FIG. 9 is a graph showing changes in viscosity of a black paste of an Example according to one or more embodiments and changes in viscosity of a black paste of a Comparative Example.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals or symbols denote like elements throughout the attached drawings and the written description, and, thus, duplicative descriptions thereof may not be provided. In the drawings, the thickness, ratio, and size of the elements may be exaggerated in order to effectively describing the technical contents. As used herein, the term “and/or” includes any and all combinations of one or more of the associated listed elements.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” “contain/containing” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, being “arranged directly on” may indicate that there is no additional layer, film, region, plate, and/or the like between a part and another part such as a layer, a film, a region, a plate, and/or the like. For example, being “arranged directly on” may indicate that two layers or two members are arranged without an additional member, such as an adhesive member, therebetween.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Herein, the phrase “a region/portion corresponds to another region/portion” indicates that “the regions/portions overlap each other”, and is not limited to having the same surface area and/or having the same shape. In addition, herein, the phrase “a region/portion and a region/portion overlap” includes a case in which a region/portion and a region/portion that are indicated as overlapping when viewed on a plane (e.g., in a plan view) overlap at least partially on the plane.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense unless, expressly so defined herein.

Hereinafter, a display module according to one or more embodiments, a method for manufacturing a display module according to one or more embodiments, and an electronic device according to one or more embodiments will be described with reference to the accompanying drawings.

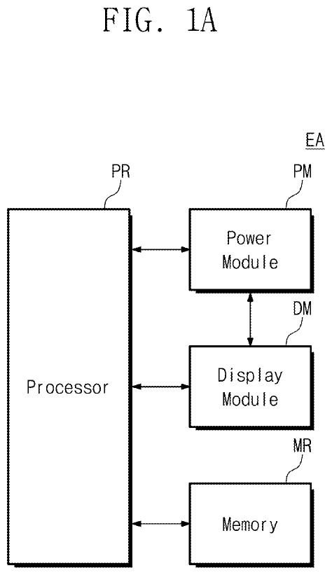

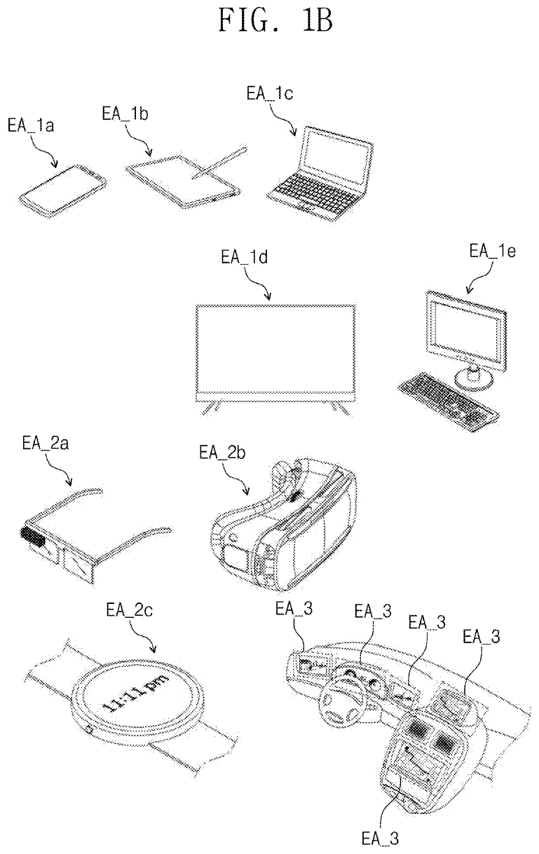

FIG. 1A is a block diagram of an electronic device according to one or more embodiments of the present disclosure. Referring to FIG. 1A, an electronic device EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information for the operation of the processor PR or the display module DM. When the processor PR executes an application stored in the memory MR, image data signals and/or input control signals may be transmitted to the display module DM, and the display module DM may process the received signal and output image information through a display screen.

The power module PM may include a power supply module such as a power adapter or a battery device, and a power conversion module that converts power supplied by the power supply module to generate power for the operation of the electronic device EA.

At least one of the components of the electronic device EA described above may be included in the display device according to one or more embodiments. In some embodiments, some of the individual modules functionally included in one module may be included in the display device, and others may be separately provided from the display device. For example, the display device may include the display module DM, which will be described in more detail later. The processor PR, the memory MR, and/or the power module PM may be provided in the form of other devices within the electronic device EA, rather than the display device.

FIG. 1B shows schematic views of electronic devices according to embodiments of the present disclosure.

Referring to FIG. 1B, various (e.g., suitable) electronic devices to which the display device according to one or more embodiments may be applied may include an electronic device for displaying images, such as a smart phone EA_1a, a tablet PC EA_1b, a laptop EA_1c, a TV EA_1d, and/or a desk monitor EA_1e, a wearable electronic device including a display module such as a smart glasses EA_2a, a head mounted display EA_2b, and/or a smart watch EA_2c, and/or a vehicle electronic device EA_3 including a display module such as a center information display (CID) and/or a room mirror display arranged on an instrument panel, a center fascia, or a dashboard of a vehicle.

A display device according to one or more embodiments may be applied to one or more suitable electronic devices. The electronic device according to one or more embodiments may further include a module or device having additional functions in addition to the display device.

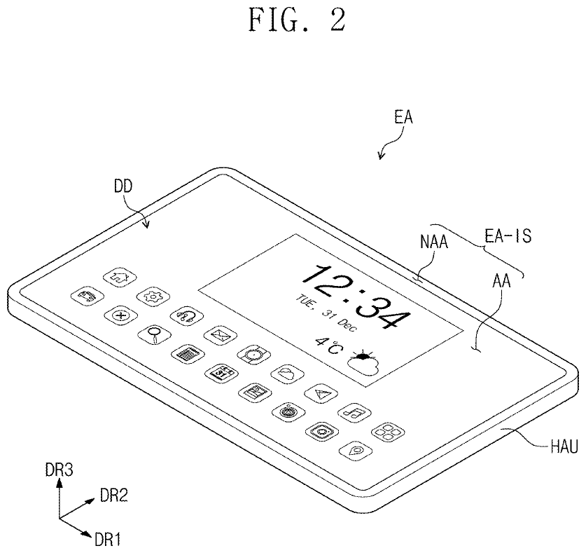

FIG. 2 is a perspective view showing an electronic device according to one or more embodiments of the present disclosure.

The electronic device EA according to one or more embodiments may include a display device DD displaying images through a display surface EA-IS. The display device DD may be housed and arranged in a housing HAU. The electronic device EA may include a display device DD and a control portion configured to control the operation of the display device DD.

When viewed on a plane (e.g., in a plan view), the display surface EA-IS of the electronic device EA may have a rectangular shape which has long sides extending in a first direction DR1 and short sides extending in a second direction DR2 crossing the first direction DR1. However, the present disclosure is not limited thereto, and the display surface EA-IS may have one or more suitable shapes such as a circular shape or a polygonal shape.

Herein, a third direction DR3 may be defined as a direction substantially normal (e.g., perpendicular) to a plane defined by the first direction DR1 and the second direction DR2. A front surface (or upper surface) and a rear surface (or lower surface) of each member constituting the electronic device EA may oppose each other in the third direction DR3 and a normal direction of each of the front and rear surfaces may substantially be parallel to the third direction DR3. A distance between the front surface and the rear surface defined along the third direction DR3 may correspond to a thickness of a member.

Herein, the phrase “on a plane” may be defined as a state viewed in the third direction DR3 (e.g., a plan view). For example, the phrase “on a plane” may be described with respect to the plane defined by both the first direction DR1 and the second direction DR2. Herein, the phrase “in a cross-section” may be defined as a state viewed in the first direction DR1 or the second direction DR2. The directions indicated by the first to third directions DR1 to DR3 are relative concepts and thus may be changed to other directions.

In FIG. 2, a tablet terminal is shown as an example of the electronic device EA. The tablet terminal may be formed by placing electronic modules, camera modules, power modules, and/or the like mounted on a motherboard in a bracket/housing HAU along with the display device DD. The present disclosure is not limited thereto, and the display device DD and a display module according to one or more embodiments, which will be described in more detail later, may be used for large-sized electronic devices such as televisions, monitors, or outdoor billboards, as well as small- and medium-sized electronic devices such as personal computers, laptop computers, personal digital terminals, car navigation units, game consoles, smartphones, tablets, smartwatches, an/or cameras. In addition, these devices are merely provided as examples, and the display device DD according to one or more embodiments may also be employed in other electronic devices so long as it does not depart from the spirit and scope of the present disclosure. The electronic device EA including the display device DD may also be referred to as a display device.

An electronic device EA including the display device DD provided with a flat display surface is shown according to one or more embodiments, but present disclosure is not limited thereto. The electronic device EA may include a curved display surface or a three-dimensional display surface. For example, the three-dimensional display surface may include a plurality of display regions indicating different directions, and may also include a bent display surface. The electronic device EA according to the one or more embodiments may be a flexible electronic device. The flexible electronic device may be a foldable electronic device.

As shown in FIG. 2, the display surface EA-IS includes an active region AA on which images are displayed and a bezel region NAA adjacent to the active region AA. The bezel region NAA is a region on which images are not displayed. In FIG. 2, icon images are shown as an example of images. The active region AA may be referred to as a display region of the display device DD, and the bezel region NAA may be referred to as a non-display region of the display device DD.

As shown in FIG. 2, the active region AA may have a substantially quadrangular shape. The term “substantially quadrangular shape” may include not only a quadrangular shape according to a mathematical meaning but also a quadrangular shape in which a curved boundary is defined in a vertex region (a corner region) as opposed to a vertex of the quadrangular shape.

The bezel region NAA may be around (e.g., surround) the active region AA. However, the present disclosure is not limited thereto, and the bezel region NAA may be modified in shape. For example, the bezel region NAA may be arranged on only one or more sides of the active region AA.

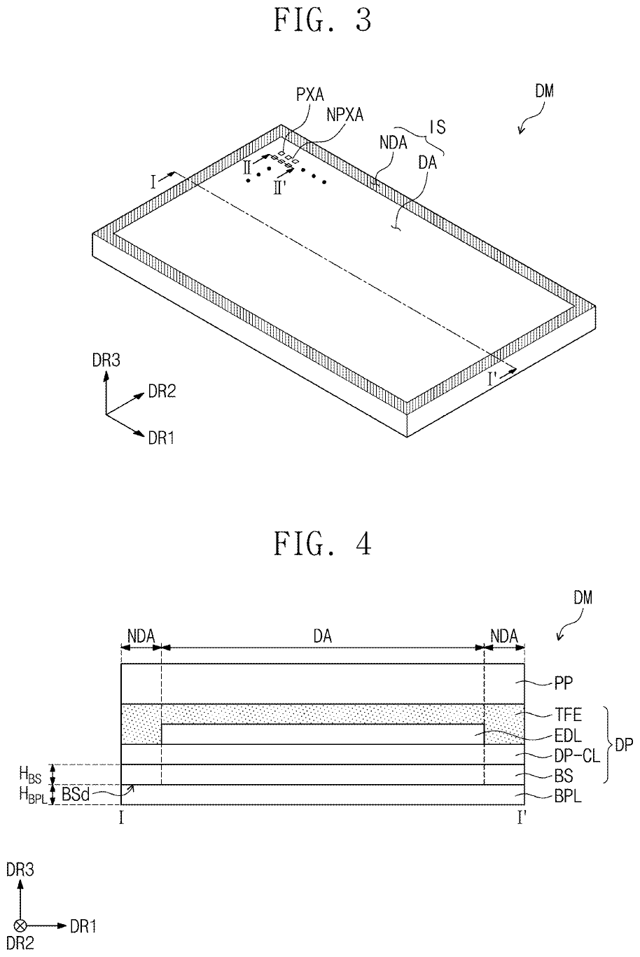

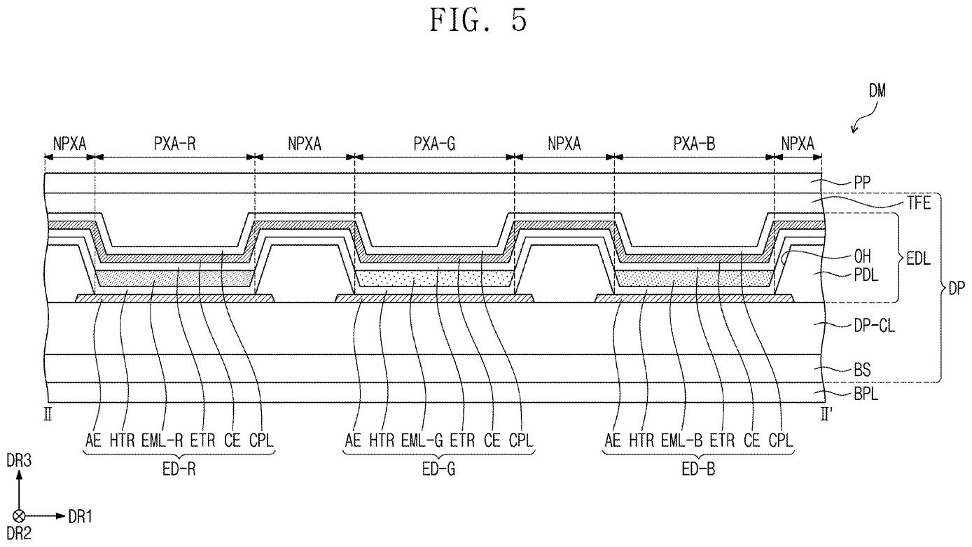

FIG. 3 is a perspective view of a display module according to one or more embodiments of the present disclosure. FIG. 4 is a cross-sectional view of a display module according to one or more embodiments of the present disclosure. FIG. 5 is a cross-sectional view showing a portion of a display module according to one or more embodiments of the present disclosure in more detail. FIG. 4 is a cross-sectional view taken along the line I-I′ of FIG. 3 according to one or more embodiments of the present disclosure, and FIG. 5 is a cross-sectional view taken along the line II-II′ of FIG. 3, according to one or more embodiments of the present disclosure. A display module DM according to one or more embodiments described with reference to FIG. 3 and/or the like may be included in the display device DD shown in FIG. 2 and/or the like.

Referring to FIG. 3, the display module DM may include a display surface IS, and the display module DM may display images through the display surface IS. The display surface IS of the display module DM may correspond to the display surface EA-IS of the electronic device EA.

The display surface IS may include a display region DA and a non-display region NDA. In the display region DA, a plurality of pixel regions PXA may be arranged. A peripheral region NPXA is arranged around the pixel regions PXA. The pixel regions PXA may be referred to as light-emitting regions, and the peripheral region NPXA may be referred to as a non-light-emitting region.

The display module DM according to one or more embodiments may include a plurality of pixel regions PXA repeatedly arranged throughout the display region DA. The pixel regions PXA in the display module DM according to one or more embodiments may be arranged in the form of a stripe if (e.g., when) viewed on a plane (e.g., in a plan view). Referring to FIG. 3, the plurality of pixel regions PXA may be aligned along the first directional axis DR1 or the second directional axis DR2. However, one or more embodiments is not limited thereto, and the pixel regions PXA may be arranged in the form of a pentile (PENTILE®) (e.g., an RGBG matrix, an RGBG structure, or RGBG matrix structure) or a diamond (Diamond Pixel®) (e.g., a display (e.g., an OLED display) containing red, blue, and green (RGB) light emitting regions arranged in the shape of diamonds). PENTILE® and Diamond Pixel® are duly registered trademarks of Samsung Display Co., Ltd. In addition, while the pixel regions PXA are shown to have areas of similar size on a plane (e.g., in a plan view) in FIG. 3 and/or the like, the present disclosure is not limited thereto, and the pixel regions PXA may have areas of different size on a plane (e.g., in a plan view) according to the wavelength range of emitted light.

The pixel regions PXA are not arranged in the non-display region NDA of the display surface IS, and the non-display region NDA may be around (e.g., surround) the display region DA. However, the present disclosure is not limited thereto, and the non-display region NDA may not be provided or may be arranged on only one or more sides of the display region DA.

Referring to FIGS. 4 and 5, the display module DM according to one or more embodiments includes a base substrate BS, a display layer EDL, and a black printing layer BPL.

Referring to FIGS. 4 and 5, the display module DM according to one or more embodiments may include a display panel DP. The base substrate BS and the display layer EDL may each be a component of the display panel DP. The display panel DP may be configured to generate images and/or image data. The display panel DP according to one or more embodiments may be a component included in the electronic device EA (see, e.g., FIG. 2), configured to display images. The display panel DP according to one or more embodiments may be a light-emitting display panel.

The display panel DP may include a base substrate BS, a circuit layer DP-CL, a display layer EDL, and an encapsulation layer TFE, which are sequentially stacked in the third directional axis DR3. For example, the display layer EDL may be arranged on an upper portion of the base substrate BS.

The display layer EDL may include light-emitting elements ED-R, ED-G, and ED-B. The plurality of pixel regions PXA-R, PXA-G, and PXA-B may each be a region emitting light generated from each of the light-emitting elements ED-R, ED-G, and ED-B.

The encapsulation layer TFE may be directly arranged on the display layer EDL. The encapsulation layer TFE may cover the light-emitting elements ED-R, ED-G, and ED-B of the display layer EDL.

Referring to FIGS. 3 and 5, the pixel regions PXA may include first to third pixel regions PXA-R, PXA-G, and PXA-B. In the display module DM according to one or more embodiments, the first to third pixel regions PXA-R, PXA-G, and PXA-B may be regions that are distinguished (e.g., spaced apart and/or separated) from each other on a plane (e.g., in a plan view) and emit light of different wavelength ranges.

In one or more embodiments, the display module DM according to one or more embodiments may include a peripheral region NPXA arranged around the first to third light-emitting regions PXA-R, PXA-G, and PXA-B. The peripheral region NPXA sets boundaries (e.g., defines a boundary) between the first to third pixel regions PXA-R, PXA-G, and PXA-B. The peripheral region NPXA may be around (e.g., surround) each of the first to third pixel regions PXA-R, PXA-G, and PXA-B. A structure that prevents or reduces color mixing between the first to third pixel regions PXA-R, PXA-G, and PXA-B, for example, a pixel-defining film PDL, may be arranged to overlap the peripheral region NPXA.

The first to third pixel regions PXA-R, PXA-G, and PXA-B may each be a region separated by the pixel-defining film PDL. The peripheral region NPXA may be a region (or shown as regions in a cross-sectional view) between neighboring the first to third pixel regions PXA-R, PXA-G, and PXA-B, and may correspond to the pixel-defining film PDL.

The first to third pixel regions PXA-R, PXA-G, and PXA-B may each be a region emitting light generated from each of the first to third light-emitting elements ED-R, ED-G, and ED-B. The first to third pixel regions PXA-R, PXA-G, and PXA-B may be spaced and/or apart (e.g., spaced apart or separated) from one another when viewed on a plane (e.g., in a plan view).

The pixel-defining film PDL may separate the first to third light-emitting elements ED-R, ED-G, and ED-B. Emission layers EML-R, EML-G, and EML-B of the first to third light-emitting elements ED-R, ED-G, and ED-B may be arranged and separated from each other in pixel openings OH defined by the pixel-defining film PDL (e.g., each of the first to third light-emitting elements ED-R, ED-G, and ED-B may be arranged in a respective pixel opening OH of a plurality of pixel openings OH that are separate from each other).

The pixel-defining film PDL may be formed of a polymer resin. For example, the pixel-defining film PDL may include a polyacrylate-based resin or a polyimide-based resin. In one or more embodiments, the pixel-defining film PDL may further include an inorganic material in addition to the polymer resin. The pixel-defining film PDL may include a light absorbing material, or may include a black pigment and/or a black dye. The pixel-defining film PDL including a black pigment and/or black dye may form a black pixel-defining film.

The first to third pixel regions PXA-R, PXA-G, and PXA-B may be divided according to the color of light generated from the first to third light-emitting elements ED-R, ED-G, and ED-B. For example, in the display module DM according to one or more embodiments, the first pixel region PXA-R may be a red light emitting region, the second pixel region PXA-G may be a green light emitting region, and the third pixel region PXA-B may be a blue light emitting region.

In the display module DM according to one or more embodiments, the light-emitting elements ED-R, ED-G, and ED-B may be to emit light having different wavelength ranges. For example, in one or more embodiments, the first light-emitting element ED-R may correspond to a red light-emitting element that emits red light, the second light-emitting element ED-G may correspond to a green light-emitting element that emits green light, and the third light-emitting element ED-B may correspond to a blue light-emitting element that emits blue light.

In FIG. 5, three distinct pixel regions PXA-R, PXA-G, and PXA-B are shown, but the present disclosure is not limited thereto, and the display module DM according to one or more embodiments may include four or more light emitting regions having different light emitting characteristics.

In the display panel DP, the base substrate BS may be a member providing a base surface on which a black printing layer BPL, a display layer EDL, and a circuit layer DP-CL are arranged. The base substrate BS may be a glass substrate, a metal substrate, a plastic substrate, and/or the like. However, the present disclosure is not limited thereto, and the base substrate BS may be an inorganic layer, an organic layer, or a complex material layer (e.g., including both an inorganic and organic material or including more than one layer of organic and/or inorganic layers).

In one or more embodiments, the base substrate BS may have a thickness HBs of about 0.1 mm or greater and less than about 0.3 mm (e.g., of about 0.1 mm to 1.3 mm). For example, the base substrate BS may have a thickness HBs of about 0.2 mm. The display module DM according to one or more embodiments may exhibit improved strength characteristics by including a black printing layer BPL arranged on one surface of the base substrate BS even if (e.g., when) the base substrate BS has a thin thickness HBs of about 0.1 mm or greater and less than about 0.3 mm (e.g., of about 0.1 mm to 1.3 mm). The black printing layer BPL will be described in more detail later.

In one or more embodiments, the circuit layer DP-CL may be arranged on the base substrate BS, and the circuit layer DP-CL may include a plurality of transistors. The transistors may each include a control electrode, an input electrode, and an output electrode. For example, the circuit layer DP-CL may include a switching transistor and a driving transistor for driving the light-emitting elements ED-R, ED-G, and ED-B of the display layer EDL.

The encapsulation layer TFE may cover the light-emitting elements ED-R, ED-G, and ED-B. The encapsulation layer TFE may seal the display layer EDL. The encapsulation layer TFE may be a thin film encapsulation layer. The encapsulation layer TFE may be a stack layer including a plurality of layers. The encapsulation layer TFE according to one or more embodiments may include at least one inorganic film and at least one organic film.

The display module DM according to one or more embodiments may include an optical member PP. The optical member PP may be a reflection reduction layer reducing reflectance of external light. For example, the optical member PP may include a polarizing film including a phase retarder and/or a polarizer, multi-layered reflection layers that induces destructive interference of reflected light, or color filters arranged corresponding to the pixel arrangement and light emitting color of the display panel DP. In one or more embodiments, the optical member PP may not be provided.

In the display module DM according to one or more embodiments, each of the first to third light-emitting elements ED-R, ED-G, and ED-B may include a first electrode AE, a hole transport region HTR, a respective emission layer EML-R, EML-G, and EML-B, an electron transport region ETR, and a second electrode CE. In one or more embodiments, each of the light-emitting elements ED-R, ED-G, and ED-B may further include a capping layer CPL arranged on the second electrode CE.

The first electrode AE may be exposed in a pixel opening OH of the pixel-defining film PDL.

The second electrode CE may be arranged on the first electrode AE. The second electrode CE may oppose the first electrode AE with the emission layers EML-R, EML-G, and EML-B therebetween. The second electrode CE may be a cathode or an anode. In one or more embodiments, if (e.g., when) the first electrode AE is an anode, the second electrode CE may be a cathode, and if (e.g., when) the first electrode AE is a cathode, the second electrode CE may be an anode. The second electrode CE may be a common electrode. The second electrode CE may be a transmissive electrode, a transflective electrode, or a reflective electrode.

For example, first electrode AE may be arranged separately to correspond to each of the pixel regions PXA-R, PXA-G, and PXA-B. The second electrode CE may be provided as a common layer throughout the pixel regions PXA-R, PXA-G, and PXA-B.

The hole transport region HTR may be arranged between the first electrode AE and the emission layers EML-R, EML-G, and EML-B, and the electron transport region ETR may be arranged between the emission layers EML-R, EML-G, and EML-B and the second electrodes CE. Referring to FIG. 5, the hole transport region HTR and the electron transport region ETR may each be provided as a common layer throughout the pixel regions PXA-R, PXA-G, and PXA-B. However, one or more embodiments is not limited thereto, and the hole transport region HTR and the electron transport region ETR may each independently be arranged separately to correspond to each of the pixel regions PXA-R, PXA-G, and PXA-B.

In one or more embodiments, each of the first to third light-emitting elements ED-R, ED-G, and ED-B may further include a capping layer CPL. The capping layer CPL may be arranged on an upper portion of the second electrode CE. The capping layer CPL may include a multi-layer or a single layer. Referring to FIG. 5, in the display module DM according to one or more embodiments, the capping layer CPL may be provided as a common layer throughout the pixel regions PXA-R, PXA-G, and PXA-B.

Referring to FIG. 4, in the display module DM according to one or more embodiments, the black printing layer BPL is spaced and/or apart (e.g., spaced apart or separated) from the display layer EDL with the base substrate BS therebetween and is arranged on a lower surface BSd of the base substrate BS. The black printing layer BPL may be a layer that blocks external light and prevents or reduces internal light leakage. In one or more embodiments, the black printing layer BPL may be a layer that alleviates or reduces impact generated or received from a lower portion of the display module DM to prevent or reduce damage to the display panel DP.

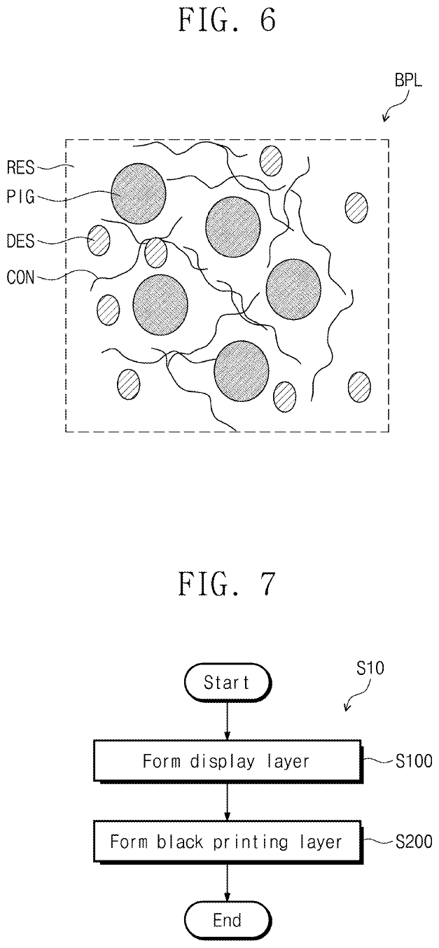

FIG. 6 is a schematic view showing a configuration of a black printing layer according to one or more embodiments of the present disclosure.

Referring to FIG. 6, the black printing layer BPL includes a base portion RES in which oligomers and monomers are polymerized, a black colorant PIG, a conductor CON, and a moisture absorbent DES. The black printing layer BPL may be formed from a black paste. The black paste indicates a mixture of black printing layer BPL materials including an oligomer and a monomer (e.g., a polymer including an oligomer and a monomer), a black colorant, a conductor, and a moisture absorbent before curing during the manufacturing process of the black printing layer BPL. A weight of the black paste indicates a weight before curing.

The oligomer indicates a molecule composed of several to several tens of repeating units. The oligomer is included as a component of a curable resin, and may be cured via light or heat to form the base portion RES of the black printing layer BPL. The oligomer may have a curing reaction group of an acrylate group and/or an epoxy group. For example, the oligomer having a curing reaction group of an acrylate group may be at least one of urethane acrylate, epoxy acrylate, polyester acrylate, or polyether acrylate. For example, the oligomer having a curing reaction group of an epoxy group may be at least one of bisphenol A epoxy oligomer, novolac epoxy oligomer, or siloxane epoxy oligomer. The oligomer may be provided in an amount of about 40 wt % or greater and less than about 60 wt % (e.g., about 40 wt % to about 60 wt %) of a total weight of the black paste.

The monomer indicates a basic unit material that forms a polymer through polymerization. The monomer is cured via light or heat together with the oligomer to form the base portion RES of the black printing layer BPL. The monomer may have a curing reactive group of an acrylate group and/or an epoxy group. For example, the monomer having a curing reactive group of an acrylate group may be at least one of methyl acrylate, ethyl acrylate, butyl acrylate, 2-hydroxyethyl acrylate, 2-hydroxypropyl acrylate, trimethylolpropane triacrylate, or phenyl acrylate. For example, the monomer having a curing reactive group of an epoxy group may be at least one of bisphenol A diglycidyl ether, bisphenol F diglycidyl ether, novolac epoxy, cycloaliphatic epoxy, or siloxane epoxy.

The oligomer and the monomer may be a base in which other additives are dispersed in the black paste resin. The base portion RES may be when the oligomer and the monomer are polymerized and cured. For example, the black paste may be a mixture including an oligomer, a monomer, a black colorant, a conductor, and a moisture absorbent prior to curing. Upon curing, the oligomer and the monomer polymerize to form the base portion RES of the black printing layer BPL. In the black printing layer BPL, the base portion RES may serve to provide physical stability such as adhesive strength and hardness.

The black colorant PIG is a material that blocks the passage of external light in the black printing layer BPL. The black printing layer BPL may include the black colorant PIG and thus exhibit light blocking properties in the display module DM. For example, the black colorant PIG may be carbon black or at least one colorant capable of absorbing visible light. The black colorant PIG may be provided in an amount of about 1 wt % or greater and less than about 10 wt % (e.g., about 1 wt % to about 10 wt %) based on a total weight of the black paste.

The conductor CON is a material that may transmit electricity and provides electrostatic discharge (ESD) protection, electromagnetic interference (EMI) shielding, and/or electrical grounding. For example, the conductor CON is a material that may be to transmit electricity, and indicates a material that functions to provide electrostatic discharge (ESD protection), electromagnetic interference (EMI) shielding, and/or electrical grounding in the black printed layer BPL. The conductor CON may be a conductive filler. For example, the conductor CON may include at least one of carbon black, carbon nanotubes, silver nanowires, graphene, or an MXene. The conductor CON may be provided in an amount of about 1 wt % or greater and less than about 5 wt % (e.g., about 1 wt % to about 5 wt %) based on a total weight of the black paste.

The moisture absorbent DES is a material that absorbs moisture from the surrounding environment. Without the moisture absorbent DES, the black paste may absorb moisture from the surrounding environment over time, and may exhibit reduced viscosity. When the black paste has low viscosity, the black paste may not be applied uniformly (e.g., substantially uniformly). Because the moisture absorbent DES absorbs moisture, the moisture absorbent DES may mitigate viscosity degradation by maintaining hydrogen bonds between black paste materials in the base portion RES. Accordingly, the black printing layer BPL according to one or more embodiments is formed from a black paste including the moisture absorbent DES and may thus exhibit improved physical properties such as uniform (e.g., substantially uniform) thickness and high surface resistance, and excellent or suitable light blocking properties.

In one or more embodiments, the moisture absorbent DES may include at least one of inorganic particles or a highly moisture absorbent polymer. The inorganic particles may be an inorganic material having high porosity, a large surface area, and strong moisture absorbency. The highly moisture absorbent polymer may have a property of absorbing moisture by including a hydrophilic functional group. The black paste, which is a material of the black printing layer BPL, may exhibit high viscosity by including the moisture absorbent DES including at least one of inorganic particles or a highly moisture absorbent polymer. Therefore, the display module DM may have excellent or suitable light blocking properties due to the uniform (e.g., substantially uniform) thickness of the black printing layer BPL, and may have excellent or suitable impact resistance against impact occurring from below.

For example, the inorganic particles may be at least one of zeolite, porous silica, metal-organic framework, alumina particle, nano clay, porous carbon, CaCl₂), NaCl, or bentonite clay. For example, the highly moisture absorbent polymer may be at least one of hemicellulose resin, pectin, silica gel, or starch particles. The metal-organic framework indicates a material in which an organic molecule and a metal element (e.g., a divalent copper cation) form a three-dimensional structure through coordination bonding. The nano clay indicates clay particles having a particle size of about 100 nm to about 1000 nm. The inorganic particles and the highly moisture absorbent polymer may exhibit high moisture absorption properties by including the materials described above.

In one or more embodiments, the black paste may further include a polymer. The polymer indicates a molecule composed of hundreds or more repeating units. The polymer is included as a component of a curable resin, and may be cured via light or heat to form the base portion RES of the black printing layer BPL together with a monomer and an oligomer. In one or more embodiments, the oligomer and the monomer may be polymerized to make up the polymer. After curing, the polymer may provide mechanical properties in the black printing layer BPL. For example, the polymer may be polyester.

In one or more embodiments, the black paste may further include a crosslinking agent. The crosslinking agent may be a substance that forms a chemical bond between polymer chains to increase the mechanical and chemical stability of materials. The crosslinking agent is chemically bonded and solidified after curing reactions are completed, and may thus not remain on the black printing layer BPL. For example, the crosslinking agent may be at least one of an epoxy-based crosslinking agent, an acryl-based crosslinking agent, or a silicone crosslinking agent. The epoxy-based crosslinking agent may include a functional group such as diamine, melamine, and isocyanate. For example, the acryl-based crosslinking agent may be at least one of dimethacrylate or trimethylolpropane triacrylate (TMPTA). For example, the silicone crosslinking agent may include a functional group such as silane and peroxide.

In one or more embodiments, the black paste may further include an initiator. The initiator may be a material capable of inducing polymerization and curing reactions of oligomers and monomers in an ultraviolet region having a wavelength of about 300 nm or greater and less than about 400 nm. For example, the initiator may include at least one of 2-hydroxy-2-methylpropiophenone or an iridium-based (IrGACURE) initiator. The initiator may be provided in an amount of about 5 wt % or greater and less than about 15 wt % (e.g., about 5 wt % to about 15 wt %) based on a total weight of the black paste.

In one or more embodiments, the black paste may further include a surfactant. The surfactant may be a material that reduces surface tension at an interface of materials having different properties to improve dispersibility and mixing properties. The surfactant may serve to support uniform (e.g., substantially uniform) dispersion of the oligomer, the monomer, the black colorant PIG, and the conductor CON in the black paste, thereby improving coating uniformity. For example, the surfactant may include a Si element. The surfactant may be provided in an amount of about 1 wt % or greater and less than about 10 wt % (e.g., about 1 wt % to about 10 wt %) based on a total weight of the black paste.

Referring to FIG. 4, in one or more embodiments, a display region DA and a non-display region NDA may be defined on a base substrate BS. The display region DA may indicate a portion corresponding to a display layer EDL. The non-display region NDA may indicate a portion arranged on at least one side of the display region DA. The non-display region NDA may be arranged to be around (e.g., surround) the display region DA at an outer edge of the display region DA. The black printing layer BPL may be arranged to entirely overlap the display region DA. When the black printing layer BPL is arranged to entirely overlap the display region DA, the display module DM may exhibit excellent or suitable display quality due to reduced light leakage. The black printing layer BPL may be arranged to overlap or non-overlap the non-display region NDA. For example, the black printing layer BPL may be arranged to entirely overlap a lower surface of the base substrate. Alternatively, in one or more embodiments, the black printing layer BPL may be arranged to overlap a portion of the non-display region NDA.

For example, the black printing layer BPL may be arranged to entirely overlap the display region DA and the non-display region NDA except for the position of an Align Key in the electronic device EA (see, e.g., FIG. 2). The Align Key indicates a reference mark for disposing patterns of each layer at an accurate position in the manufacturing process of display. Because the alignment of each layer may not be accurately performed in a subsequent process if (e.g., when) the Align Key is covered with the black printing layer BPL, the black printing layer BPL may not overlap the position of Align Key.

Referring to FIG. 4, in one or more embodiments, the black printing layer BPL may be formed by applying a black paste to a thickness of about 8 μm or greater and less than about 14 μm. Because the black paste according to one or more embodiments may maintain high viscosity during the manufacturing process by including the moisture absorbent DES, the black paste is applied to have a uniform (e.g., substantially uniform) thickness even if (e.g., when) applied to be thick with a thickness of about 8 μm or greater and less than about 14 μm, and thus the black printing layer BPL according to one or more embodiments may exhibit excellent or suitable light blocking properties. A thickness H_{BPL} of the black printing layer BPL may be the same as or different from the thickness to which the black paste is applied.

In the display module DM according to one or more embodiments, the black printing layer BPL may have a surface resistance of about 10⁶ ohm/sq or greater and less than about 10¹⁰ ohm/sq (e.g., about 10⁶ ohm/sq to about 10¹⁰ ohm/sq). Because the black paste may maintain high viscosity during the manufacturing process by including the moisture absorbent DES, the black paste may be applied uniformly (e.g., substantially uniformly). Accordingly, the black printing layer BPL may exhibit high surface resistance with a surface resistance of about 10⁶ ohm/sq or greater and less than about 10¹⁰ ohm/sq (e.g., about 10⁶ ohm/sq to about 10¹⁰ ohm/sq).

In the display module DM according to one or more embodiments, the black printing layer BPL may have a pencil hardness of about 1H or greater and less than about 6H (e.g., about 1H to about 6H). Because the moisture absorbent DES absorbs moisture and maintains hydrogen bonding between black paste materials, the black printing layer BPL may exhibit high pencil hardness with a pencil hardness of about 1H or greater and less than about 6H (e.g., about 1H to about 6H).

The display module DM according to one or more embodiments includes a black printing layer BPL arranged on a lower surface BSd of the base substrate BS, and the black printing layer BPL includes the moisture absorbent DES, and may thus exhibit excellent or suitable light blocking properties. For example, the moisture absorbent DES may be to absorb moisture during the process of forming the black printing layer BPL and may thus maintain the black paste at a high viscosity. Therefore, the black printing layer BPL may have high surface resistance and high hardness and have a uniform (e.g., substantially uniform) thickness. Therefore, the display module DM according to one or more embodiments may exhibit excellent or suitable physical properties and reduced light leakage.

The display module DM according to one or more embodiments described with reference to FIGS. 3 to 5, and/or the like, and the black printing layer BPL according to one or more embodiments described with reference to FIG. 6 and/or the like may be included in an electronic device according to one or more embodiments.

Referring to FIG. 2, the electronic device EA according to one or more embodiments includes a display module DM that generates images, and the display module DM includes the base substrate, the display layer, and the black printing layer described above, and may thus may incorporate the features of the display module DM described above.

The electronic device according to one or more embodiments includes the display module according to one or more embodiments described above, and may thus exhibit improved physical properties, excellent or suitable display quality, and excellent or suitable reliability.

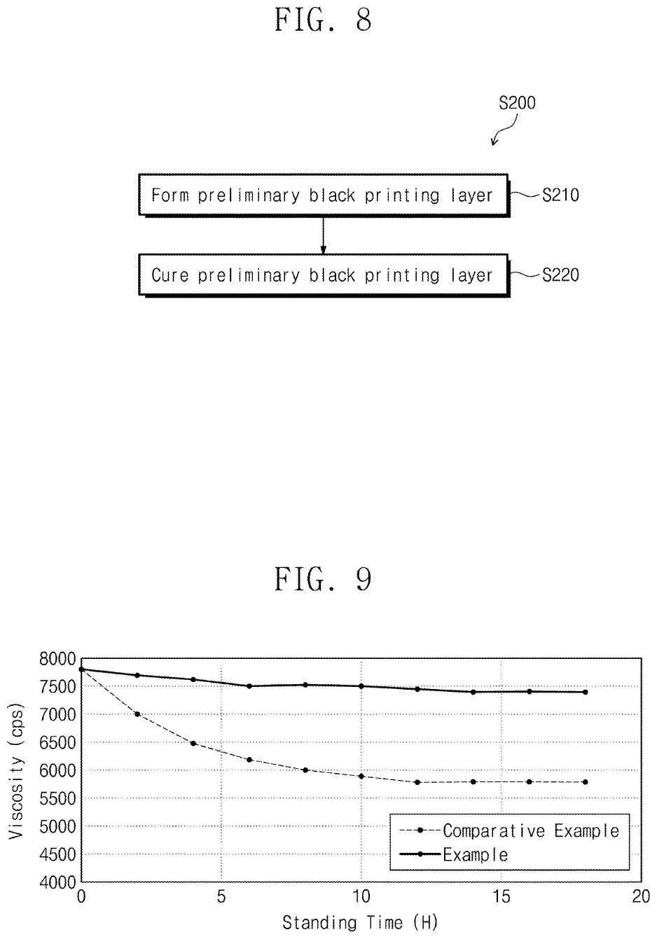

Hereinafter, a method for manufacturing a display module according to one or more embodiments will be described with reference to FIGS. 7 and 8. In the description of the method for manufacturing a display module according to one or more embodiments, overlapping descriptions with respect to the display module DM according to one or more embodiments described with reference to FIGS. 3 to 5 and/or the like and the black printing layer BPL according to one or more embodiments described with reference to FIG. 6 and/or the like may not be provided again, and the differences may be mainly described.

FIG. 7 is a flowchart showing a method for manufacturing a display module according to one or more embodiments of the present disclosure. FIG. 8 is a flowchart showing a method for manufacturing a black printing layer according to one or more embodiments of the present disclosure.

Referring to FIG. 7, a method for manufacturing a display module according to one or more embodiments (S10) includes forming a display layer (S100) and forming a black printing layer (S200).

In the forming of a display layer (S100), a display layer including a light-emitting element is formed on a base substrate BS. The base substrate BS may have a thickness of about 0.1 mm or greater and less than about 0.3 mm (e.g., of about 0.1 mm to 1.3 mm). For example, the base substrate BS may be provided to have a thickness of about 0.2 mm.

In the forming of a black printing layer (S200), a black printing layer BPL is formed on a lower surface of the base substrate to be spaced and/or apart (e.g., spaced apart or separated) from the display layer with the base substrate BS therebetween, and the black printing layer BPL is formed from a black paste containing an oligomer, a monomer, a black colorant, a conductor, and a moisture absorbent.

The method for manufacturing a display module according to one or more embodiments (S10) includes a process of forming a black printing layer BPL using a high-viscosity black paste containing a moisture absorbent, and may thus uniformly (e.g., substantially uniformly) form a black printing layer BPL and reduce printing defects.

Referring to FIG. 8, in one or more embodiments, the forming of a black printing layer BPL (S200) may include forming a preliminary black printing layer (S210) and curing the preliminary black printing layer (S220).

In the forming of a preliminary black printing layer (S210), the black paste may be screen-printed or inkjet-printed to form a preliminary black printing layer. For example, the preliminary black printing layer may refer to a state before the black paste is cured after being applied to the lower surface of the base substrate BS.

Screen printing is a printing process that forms a black printing layer BPL using a mesh stencil. This is a method of printing by forcibly pushing ink onto a surface of a base substrate BS using a squeegee. The ink may be a black paste. Backside emulsion is a photosensitive material applied onto a backside (back) of a screen mesh in a screen printing process, and serves to prevent or reduce the likelihood of ink unnecessarily passing through specific areas. When the black paste has low viscosity due to moisture absorption or other reasons, the black paste may form on the backside emulsion, which may cause printing defects during application.

In the forming of a black printing layer BPL according to one or more embodiments (S200), the black printing layer BPL is formed by screen printing a black paste containing a moisture absorbent. This allows the moisture absorbent to absorb moisture, and thus the black paste may mitigate viscosity degradation. Therefore, the phenomenon of the black paste forming on the backside emulsion may be reduced, and application defects may be reduced. In one or more embodiments, because the black paste has high viscosity, the phenomenon of ink spreading at the boundary of an application target area may be reduced.

Inkjet printing is a printing process that sprays ink using a nozzle for application. The ink may be a black paste. In the forming of a black printing layer BPL according to one or more embodiments (S200), the black printing layer BPL may be formed by inkjet printing a black paste containing a moisture absorbent. This allows the black paste to have high viscosity, and thus coating defects may be reduced as in the case of screen printing. In one or more embodiments, the phenomenon of ink spreading at the boundary of an application target area may be reduced.

In the curing of a preliminary black printing layer (S220), ultraviolet (UV) or heat may be used to cure the preliminary black printing layer. For example, the preliminary black printing layer may be cured by emitting ultraviolet ray having a wavelength of about 300 nm or greater and less than about 400 nm.

In one or more embodiments, in the forming of a preliminary black printing layer (S210), the black paste may be printed on the lower surface of the base substrate with a thickness of about 8 μm or greater and less than about 14 μm. Because the black paste may maintain high viscosity without viscosity reduction by including a moisture absorbent, the black paste is applied to have a uniform (e.g., substantially uniform) thickness even if (e.g., when) applied to a thickness of about 8 μm or greater and less than about 14 μm, and thus the display module may exhibit excellent or suitable light blocking properties.

In one or more embodiments, in the forming of a black printing layer (S200), the moisture absorbent may be provided in an amount of about 1 wt % or greater and less than about 10 wt % (e.g., about 1 wt % to about 10 wt %) of a total weight of the black paste. A weight of the black paste may indicate a weight before curing. When the weight of the moisture absorbent is provided in an amount of less than about 1 wt % of the total weight of the black paste, moisture absorption is insignificant, and thus, coating defects may occur in the forming of a black printing layer (S200). When the weight of the moisture absorbent is provided in an amount of about 10 wt % or greater based on the total weight of the black paste, the black printing layer BPL may exhibit degradation in physical properties, such as low hardness or low surface resistance.

In one or more embodiments, in the forming of a black printing layer BPL (S200), the oligomer may be provided in an amount of about 40 wt % or greater and less than about 60 wt % (e.g., about 40 wt % to about 60 wt %) of a total weight of the black paste. When the weight of the oligomer is provided in an amount of about 40 wt % or greater and less than about 60 wt % (e.g., about 40 wt % to about 60 wt %) of the total weight of the black paste, even if (e.g., when) the black paste includes a moisture absorbent, the black printing layer BPL after curing may exhibit excellent or suitable physical properties such as high surface resistance, high pencil hardness, and high adhesive strength.

In one or more embodiments, the black paste may further include an initiator and a surfactant. The black colorant PIG may be provided in an amount of about 1 wt % or greater and less than about 10 wt % (e.g., about 1 wt % to about 10 wt %) of a total weight of the black paste. The conductor CON may be provided in an amount of about 1 wt % or greater and less than about 5 wt % (e.g., about 1 wt % to about 5 wt %) of a total weight of the black paste. The initiator may be provided in an amount of about 5 wt % or greater and less than about 15 wt % (e.g., about 5 wt % to about 15 wt %) of a total weight of the black paste. The surfactant may be provided in an amount of about 1 wt % or greater and less than about 10 wt % (e.g., about 1 wt % to about 10 wt %) of a total weight of the black paste. When the oligomer, the black colorant PIG, the conductor CON, the moisture absorbent DES, the initiator, and the surfactant satisfy the weight ranges described above, the black paste may maintain high viscosity while the black printing layer BPL may exhibit excellent or suitable performance in physical properties such as surface resistance, pencil hardness, and adhesive strength.

Without the moisture absorbent, the black paste may have a viscosity reduced to less than about 10% of an initial viscosity after about 18 minutes at about 30 °C and about 85% relative humidity. The black paste may maintain high viscosity even after being left for a certain period of time by including a moisture absorbent. The conditions will be described in more detail later.

FIG. 9 is a graph showing changes in viscosity of a black paste of an Example according to one or more embodiments and changes in viscosity of a black paste of a Comparative Example.

In one or more embodiments, the black paste according to one or more embodiments is a black paste including 3 wt % polyester, 35 wt % urethane acrylate oligomer, 20 wt % epoxy-based oligomer, 10 wt % acrylate-based monomer, 15 wt % 6-functional acrylic crosslinking agent, 1.1 wt % carbon black, 0.9 wt % Si-based surfactant, 10 wt % initiator, and 5 wt % zeolite, applied onto a 0.2 mm thick glass base substrate. A black paste of Comparative Example is a black paste including 50 wt % urethane acrylate oligomer, 30 wt % acrylate-based monomer, 18 wt % 5-functional acrylic crosslinking agent, 1 wt % carbon black, 10 wt % initiator, and 1 wt % carbon nanotube, applied onto a 0.2 mm thick glass base substrate. Thereafter, the black paste according to one or more embodiments (e.g., the Example) and the black paste of the Comparative Example were each left at about 30 °C and about 85% relative humidity, and viscosity was measured every 2 minutes, for a total of 10 measurements.

Referring to FIG. 9, the black paste according to the Example, which included a moisture absorbent, maintained high viscosity over time compared to the black paste of Comparative Example without a moisture absorbent. For example, the black paste of the Example and the black paste of the Comparative Example initially showed similar viscosities of about 7700 cps, but after 18 minutes, the black paste of the Example maintained a high viscosity of about 7300 cps, showing a viscosity decrease of about 5%. Conversely, after 18 minutes, the black paste of the Comparative Example showed a low viscosity of about 5750 cps, showing a viscosity decrease of about 25%. Therefore, it is determined that the black paste of the Example according to one or more embodiments showed high viscosity due to the inclusion of a moisture absorbent.

Table 1 compares the physical properties of the black printed layer according to one or more embodiments (e.g., the Example) and a black printed layer of the Comparative Example after curing.

The black printing layer of the Example in Table 1 has the same composition as the black paste of the Example in the above viscosity change measurement with the addition that the black paste has been cured by ultraviolet irradiation. The black printing layer of the Comparative Example in Table 1 has the same composition as the black paste of the Comparative Example in the above viscosity change measurement with the addition that the black paste of the Comparative Example has been cured by ultraviolet irradiation. Surface resistance is an average value of three measurements using a surface resistance measuring device ST-4 from ATOZLAB. Pencil hardness is measured by applying a force of 750 g to the black printing layer surface using an ASTM D3363 pencil hardness measuring device and scratching the surface at a 45 degree angle with a pencil. Adhesive strength is measured by performing an X-Cut Tape Test using an ASTM D3359 adhesive strength measuring device.

TABLE 1

| | Black print layer of the | Black print layer of the |
|---|---|---|
| | Example | Comparative Example |
| Surface resistance | 10⁹ ohm/sq | 10⁶ ohm/sq |
| Pencil hardness | 2H | 2H |
| Adhesive strength | 5B | 5B |

Referring to Table 1, the black printing layer according to the Example, which includes a moisture absorbent exhibited higher surface resistance while exhibiting the same pencil hardness and adhesive strength as the black printing layer of Comparative Example. Accordingly, it is determined that the black printing layer of the Example according to one or more embodiments exhibits excellent or suitable physical properties by including a moisture absorbent.

A display module according to one or more embodiments includes a black printing layer containing a moisture absorbent, and may thus provide a display module exhibiting superior performance in physical properties, such as surface resistance, and reduced light leakage.

A method for manufacturing a display module according to one or more embodiments includes forming a black printing layer from a black paste containing a moisture absorbent, and may provide a display module including a black printing layer with a uniform (e.g., substantially uniform) thickness and reduced coating defects resulting from mitigated viscosity degradation of the black paste due to the moisture absorbent.

An electronic device according to one or more embodiments includes a display module according to one or more embodiments of the present disclosure, and may thus exhibit improved durability and excellent or suitable display quality characteristics.

For example, the one or more embodiments described herein collectively provide a display module and an electronic device that achieve enhanced optical performance, mechanical durability, and environmental stability by incorporating a black printing layer on a lower surface of a base substrate, spaced from the display layer. The black printing layer, formed from a black paste including a polymerized oligomer and monomer, a black colorant, a conductor, and a moisture absorbent, enables uniform thickness and mitigates viscosity degradation during processing, thereby reducing coating defects. As a result, the display module exhibits improved light blocking, reduced light leakage, and stable electrical and mechanical properties, such as a surface resistance of about 10⁶ to about 10¹⁰ ohms per square (Ω/□) and a pencil hardness of about 1H to about 6H. These features, combined with the disclosed composition ranges and manufacturing techniques, allow integration into various electronic devices, including televisions, monitors, smartphones, tablets, and wearable devices, while maintaining excellent display quality and reliability.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display module comprising:
a base substrate;
a display layer on the base substrate and comprising a light-emitting element; and
a black printing layer spaced from the display layer with the base substrate therebetween and on a lower surface of the base substrate,
wherein the black printing layer comprises a base portion comprising a polymer that comprises polymerized oligomer and monomer, a black colorant, a conductor, and a moisture absorbent.

2. The display module of claim 1, wherein the moisture absorbent comprises at least one of inorganic particles or a highly moisture absorbent polymer.

3. The display module of claim 2, wherein the inorganic particles are at least one of zeolite, porous silica, metal-organic framework, alumina particles, nano clay, porous carbon, CaCl₂), NaCl, or bentonite clay, and
the highly moisture absorbent polymer is at least one of hemicellulose resin, pectin, silica gel, or starch particles.

4. The display module of claim 1, wherein a display region corresponding to the display layer and a non-display region on at least one side of the display region are defined on the base substrate, and
the black printing layer entirely overlaps the display region.

5. The display module of claim 1, wherein the base substrate has a thickness of 0.1 mm to 0.3 mm.

6. The display module of claim 1, wherein the black printing layer has a surface resistance of 10⁶ ohm/sq to 10¹⁰ ohm/sq.

7. The display module of claim 1, wherein the black printing layer has a pencil hardness of 1H to 6H.

8. A method comprising:
forming a display layer comprising a light-emitting element on a base substrate; and
forming a black printing layer on a lower surface of the base substrate and spaced from the display layer with the base substrate therebetween,
wherein the black printing layer is formed from a black paste containing an oligomer, a monomer, a black colorant, a conductor, and a moisture absorbent, and
wherein the method is a method for manufacturing the display module.

9. The method of claim 8, wherein the forming of the black printing layer comprises:
screen printing or inkjet printing the black paste to form a preliminary black printing layer; and
curing the preliminary black printing layer.

10. The method of claim 9, wherein in the forming of the black printing layer,
the black paste is printed to a thickness of 8 μm to 14 μm thick on the lower surface of the base substrate.

11. The method of claim 8, wherein the moisture absorbent is provided in an amount of 1 wt % to 10 wt % based on a total weight of the black paste.

12. The method of claim 8, wherein the oligomer is provided in an amount of 40 wt % to 60 wt % based on a total weight of the black paste.

13. The method of claim 8, wherein the black paste further comprises an initiator and a surfactant, and
with respect to a total weight of the black paste,
the oligomer is provided in an amount of 40 wt % to 60 wt %,
the black colorant is provided in an amount of 1 wt % to 10 wt %,
the conductor is provided in an amount of 1 wt % to 5 wt %,
the moisture absorbent is provided in an amount of 1 wt % to 10 wt %,
the initiator is provided in an amount of 5 wt % to 15 wt %, and
the surfactant is provided in an amount of 1 wt % to 10 wt %.

14. The method of claim 8, wherein the black paste has a viscosity reduced by at most 10% from an initial viscosity after 18 minutes at 30 °C and 85% relative humidity.

15. The method of claim 8, wherein the moisture absorbent comprises at least one of inorganic particles or a highly moisture absorbent polymer,
the inorganic particles are at least one of zeolite, porous silica, metal-organic framework, alumina particles, nano clay, porous carbon, CaCl₂, NaCl, or bentonite clay, and
the highly moisture absorbent polymer is at least one of hemicellulose resin, pectin, silica gel, or starch particles.

16. An electronic device comprising:
a display module configured to generate images,
wherein the display module comprises:
a base substrate;
a display layer on the base substrate and comprising a light-emitting element; and
a black printing layer spaced from the display layer with the base substrate therebetween and on a lower surface of the base substrate,
wherein the black printing layer comprises a base portion comprising a polymer that comprises polymerized oligomer and monomer, a black colorant, a conductor, and a moisture absorbent.

17. The electronic device of claim 16, wherein the moisture absorbent comprises at least one of inorganic particles or a highly moisture absorbent polymer,
the inorganic particles are at least one of zeolite, porous silica, metal-organic framework, alumina particles, nano clay, porous carbon, CaCl₂), NaCl, or bentonite clay, and
the highly moisture absorbent polymer is at least one of hemicellulose resin, pectin, silica gel, or starch particles.

18. The electronic device of claim 16, wherein the black printing layer has a surface resistance of 10⁶ ohm/sq to 10¹⁰ ohm/sq, and a pencil hardness of 1H to 6H.

19. The electronic device of claim 16, further comprising at least one of a processor, a memory, or a power module.

20. The electronic device of claim 16, wherein the electronic device is a television, a monitor, an outdoor billboard, a personal computer, a laptop computer, a personal digital terminal, an in-vehicle device, a game console, a smartphone, a tablet, a smartwatch, or a camera.
